(19) United States
(12) Patent Application Publication
(10) Pub. No.: US 2024/0120287 A1
(43) Pub. Date: Apr. 11, 2024

(54) OVERLAY MARK, MANUFACTURING METHOD USING THE SAME, AND SEMICONDUCTOR DEVICE USING THE SAME

(71) Applicant: Samsung Electronics Co., Ltd., Suwon-si (KR)

(72) Inventors: Sang Won PARK, Suwon-si (KR); A Yeong CHA, Suwon-si (KR); Byeong-Hwan SON, Suwon-si (KR); Hye Jin LEE, Suwon-si (KR); Jung Hyun CHOI, Suwon-si (KR); Jong Hee HAN, Suwon-si (KR)

(73) Assignee: Samsung Electronics Co., Ltd., Suwon-si (KR)

(21) Appl. No.: 18/480,148

(22) Filed: Oct. 3, 2023

(30) Foreign Application Priority Data
Oct. 5, 2022 (KR) 10-2022-0126680

(51) Int. Cl. H01L 23/544; G03F 7/00

(52) U.S. Cl. CPC H01L 23/544; G03F 7/70633; H01L 2223/54426

(57) ABSTRACT

Provided is an overlay mark. The overlay mark comprises a substrate, a lower overlay in the substrate, a pattern layer on the substrate, and an upper overlay defining an opening on the pattern layer. The lower overlay does not overlap the upper overlay in a thickness direction of the substrate.

### CROSS-REFERENCE TO RELATED APPLICATION

This application claims priority from Korean Patent Application No. 10-2022-0126680 filed on Oct. 5, 2022 in the Korean Intellectual Property Office, and all the benefits accruing therefrom under 35 U.S.C. 119, the contents of which in its entirety are herein incorporated by reference.

### BACKGROUND

Various example embodiments relate to an overlay mark, a fabrication method using the same, and a non-volatile memory device manufactured using the same.

In order to satisfy or at least partially satisfy the performance and low price expectations of consumers, it may be required or expected to increase a degree of integration of a non-volatile memory device. In a case of semiconductor devices such as non-volatile memory device, since the degree of integration is an important factor in determining the price of the product, in particular, an increased degree of integration is required or expected. In the case of a two-dimensional or planar non-volatile memory device, the degree of integration is largely determined by an area occupied by a unit memory cell, and is therefore greatly affected by the level of fine pattern forming technology. However, since miniaturization of patterns may use extremely expensive apparatuses, the degree of integration of the two-dimensional non-volatile memory devices is increasing, but is still limited. Therefore, three-dimensional non-volatile memory devices including memory cells arranged three-dimensionally have been proposed.

Nonetheless, in the process of manufacturing the three-dimensional non-volatile memory device, an overlay mark may be used to check a misalignment between the layers. However, it may be difficult to accurately measure data of the lower overlay mark due to the high number of steps, and an accurate inspection of misalignment between the layers may be difficult accordingly.

### SUMMARY

Various example embodiments provide an overlay mark having improved reliability.

Alternatively or additionally, variously example embodiments may also provide a pattern misalignment inspection method having improved reliability.

Alternatively or additionally, variously example embodiments may also provide a non-volatile memory device having improved reliability.

However, example embodiments are not restricted to the one set forth herein. The above and other aspects will become more apparent to one of ordinary skill in the art to which the example embodiments pertains by referencing the detailed description of various embodiments given below.

According to some example embodiments, there is provided an overlay mark comprising a substrate, a lower overlay in the substrate, a pattern layer on the substrate, and an upper overlay that defines an opening on the pattern layer. The lower overlay does not overlap the upper overlay in a thickness direction of the substrate.

Alternatively or additionally according to some example embodiments, there is provided a semiconductor fabrication method comprising forming a lower overlay in a substrate, forming a pattern layer on the substrate, forming an upper overlay that defines an opening on the pattern layer, wherein the lower overlay completely overlaps the opening in a thickness of the substrate, measuring a first peak value of the lower overlay, measuring a second peak value of the upper overlay, and calculating a difference between the first peak value and the second peak value.

Alternatively or additionally according to some example embodiments, there is provided a semiconductor device comprising a substrate including a shot region and a scribe lane region surrounding the shot region, a mold structure on the substrate of the shot region, and includes a plurality of gate electrodes and a plurality of mold insulating films alternately stacked, a dummy mold structure which is disposed on the substrate of the scribe lane region, and includes a plurality of dummy gate electrodes and a plurality of dummy mold insulating films alternately stacked, a channel structure which penetrates the mold structure and is connected to the plurality of gate electrodes, and a lower overlay n the substrate of the scribe lane region. The lower overlay includes outer walls opposite to each other, and a distance between the outer walls is 6 μm (micron) or more and 9 μm (micron) or less.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view showing a configuration before cutting a non-volatile memory device according to some example embodiments into chips and/or die.

FIG. 2 is an enlarged view of a region P of FIG. 1.

FIG. 3 is a plan view for explaining the overlay mark according to some example embodiments.

FIG. 4 is a cross-sectional view taken along line A1-Al of FIG. 3.

FIG. 5 is a plan view for explaining the overlay mark according to some example embodiments.

FIG. 6 is a plan view for explaining the overlay mark according to some example embodiments.

FIG. 7 is a cross-sectional view taken along line A2-A2 of FIG. 6.

FIG. 8 is a flow chart for explaining the pattern misalignment inspection method using the overlay mark according to some example embodiments.

FIGS. 9 to 11 are example diagrams for explaining a pattern misalignment inspection method using the overlay mark according to some example embodiments.

FIG. 12 is an example block diagram for explaining the non-volatile memory device according to some example embodiments.

FIG. 13 is an example circuit diagram of a non-volatile semiconductor memory device according to some example embodiments.

FIG. 14 is an example cross-sectional view taken along lines B-B and C-C of FIG. 2.

FIG. 15 is an enlarged view of a region Q of FIG. 14.

FIGS. 16 and 17 are example diagrams for explaining a non-volatile memory device according to some example embodiments.

FIG. 18 is an example block diagram for explaining an electronic system according to some example embodiments.

FIG. 19 is an example perspective view for explaining the electronic system according to some example embodiments.

FIG. 20 is a schematic cross-sectional view taken along a line I-I of FIG. 19.

### DETAILED DESCRIPTION

Hereinafter, various example embodiments according to some technical concepts will be described with reference to the accompanying drawings.

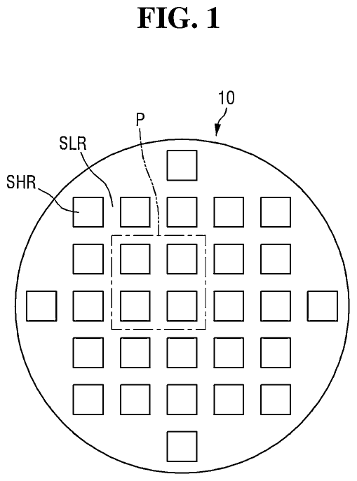

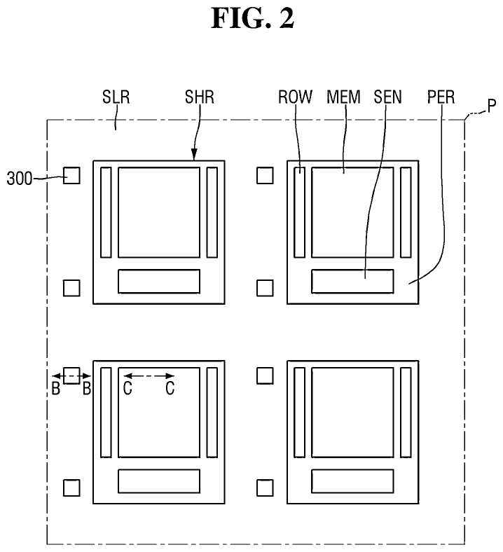

FIG. 1 is a plan view showing a configuration before cutting a non-volatile memory device according to some example embodiments of the present disclosure into chips. FIG. 2 is an enlarged view of a region P of FIG. 1.

Referring to FIGS. 1 and 2, before being cut into chips or die, a semiconductor device such as a non-volatile memory device 10 according to some example embodiments may include a plurality of shot regions SHR, and a scribe lane region SLR that surrounds the shot regions SHR.

The shot regions SHR may be arranged on a substrate such as a wafer, such as a 200 mm diameter wafer or a 300 mm diameter wafer or a 450 mm diameter wafer. The wafer may be or may include silicon such as single-crystal silicon; however, example embodiments are not limited thereto. In some example embodiments, the wafer may include a notch (not shown) and/or a flat (not shown). Furthermore, The number of and/or the arrangement of the shot regions SHR are not limited to those disclosed in FIG. 1, and there may be more or less shot regions SHR than those disclosed in FIG. 1.

The shot regions SHR are arranged in the form of a grid, such as a rectangular or square grid, with the scribe lane region SLR interposed therebetween. After being cut into chips, the non-volatile memory device 10 has substantially the same size as the shot region SHR. When the semiconductor device such as the non-volatile memory device 10 is cut into chips, the scribe lane region SLR may be partially and/or entirely lost due to dicing.

In some example embodiments, the shot region SHR may include at least one or more memory regions MEM and a one or more peripheral regions PER. The peripheral region PER may be a region outside the memory region MEM. The peripheral region PER may include a row decoder ROW and a sense amplifier SEN.

Although FIG. 2 shows that the memory region MEM is placed at the center of the shot region SHR, the row decoders ROW are placed on one side and the other side of the memory region MEM, and the sense amplifier SEN is placed in a lower part of the memory region MEM, this is only for convenience of explanation, and the technical idea of the present disclosure is not limited thereto.

In some example embodiments, a plurality of memory cells may be arranged three-dimensionally in the memory region MEM. F, the non-volatile memory device 10 according to some example embodiments may be a three-dimensional memory device. A word line of the non-volatile memory device 10 may be connected to each of the plurality of memory cells in a stacked structure. Also, the word line may be extracted stepwise and connected to a row decoder ROW or the like.

The row decoder ROW and the sense amplifier SEN may contribute to the operation of the memory cell. The row decoder ROW may specify a memory cell to operate. The sense amplifier SEN may sense and/or amplify data stored in the memory cell. Although FIG. 2 illustrates that each shot region SHR includes two row decoders ROW and one sense amplifier SEN, example embodiments are not limited thereto, and there may be more or fewer row decoders ROW and sense amplifiers SEN. Additionally or alternatively, a shape of the shot region SHR may be rectangular, e.g. may be square; example embodiments are not limited thereto. In some example embodiments, the number of chips or die in each shot region SHR may be more than one, e.g. may be two or four or six or eight or nine or more; example embodiments are not limited thereto.

A plurality of overlay marks 300 may be placed in the scribe lane region SLR. The overlay marks 300 may be placed on one side and/or the other side of the shot region SHR and/or one corner of the shot region. Misalignment of the pattern may be inspected, using the overlay marks 300 according to some example embodiments. In some example embodiments, the non-volatile memory 10 may be fabricated based on the inspection Detailed contents thereof will be described below. The number and/or the positioning of the overlay marks 300 are not limited to those described in FIG. 2.

The overlay marks according to some example embodiments will be described below in detail.

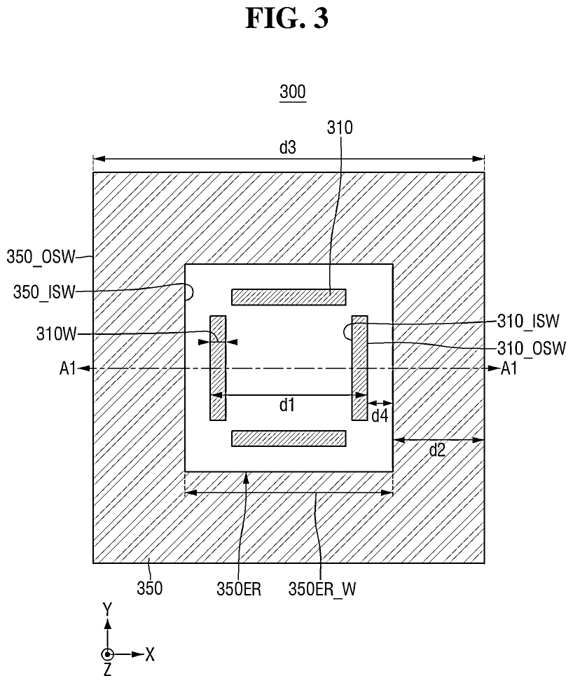

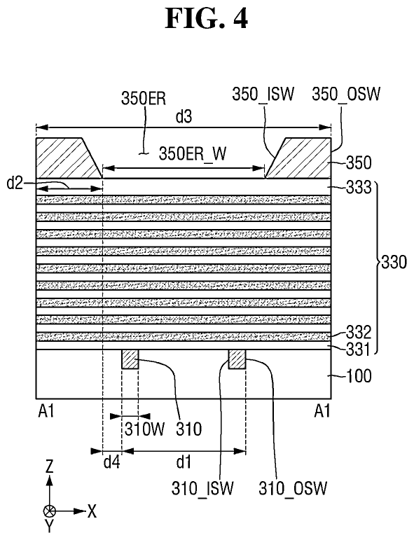

FIG. 3 is a plan view for explaining the overlay mark according to some example embodiments of the present disclosure. FIG. 4 is a cross-sectional view taken along line A1-A1 of FIG. 3.

Referring to FIGS. 3 and 4, the overlay mark 300 according to some example embodiments may include a substrate 100, a lower overlay 310, a pattern layer 330, and an upper overlay 350.

The substrate 100 may be or may include, for example, a semiconductor substrate such as a silicon substrate, a germanium substrate or a silicon-germanium substrate. The substrate 100 may include a silicon-on-insulator (SOI) substrate, a germanium-on-insulator (GOI) substrate, or the like. In some example embodiments, the substrate 100 may include impurities. For example, the substrate 100 may include n-type impurities (e.g., phosphorus (P), arsenic (As), etc.).

The lower overlay 310 may be placed inside the substrate 100. The lower overlay 310 may have a bar shape from a planar viewpoint. For example, the lower overlay 310 has a first portion that has a rectangular shape including a long side extending in a first direction X and a short side extending in a second direction Y, and a second portion that has a rectangular shape including a long side extending in the first direction X and a short side extending in the second direction Y. The first portions may be spaced apart from each other in the second direction Y, and the second portions may be spaced apart from each other by the same amount or by a different amount in the first direction X.

Herein, the first direction X, the second direction Y, and the third direction Z may intersect each other. The first direction X, the second direction Y, and the third direction Z may be substantially perpendicular to each other. The third direction Z may be a thickness direction of the substrate 100.

The lower overlay 310 may be formed of or may include a material different from that of the substrate 100. For example, the lower overlay 310 may include an insulating material such as a silicon oxide film and/or a silicon nitride film, and may include a conductive material such as metal such as tungsten and/or aluminum and/or titanium. In an example, although the lower overlay 310 may be formed of a silicon oxide film, the technical idea of the present disclosure is not limited thereto.

A pattern layer 330 may be placed on the substrate 100. The pattern layer 330 may include a plurality of first insulating layers 331, a plurality of second insulating layers 332, and a third insulating layer 333. The plurality of first insulating layers 331 and the plurality of second insulating layers 332 may be alternately stacked. A thickness of each of the plurality of first insulating layers 331 may be the same as each other, or may be different from one another; a thickness of each of the plurality of second insulating layers 332 may be the same as each other, or may be different than one another, and may or may not be the same as a thickness of each of the plurality of first insulating layers 331. The third insulating layer 333 may be placed at the top of the pattern layer 330.

In some example embodiments, the first insulating layer 331 and the third insulating layer 333 may each be formed of a silicon oxide film and may or may not include silicon nitride, and the second insulating layer 332 may be formed of a silicon nitride film and may or may not include silicon oxide. However, example embodiments are not limited thereto, and the pattern layer 330 may be formed of a single layer.

The upper overlay 350 may be placed on the pattern layer 330. The upper overlay 350 may include an opening 350ER. The opening 350ER may expose a part of the upper surface of the pattern layer 330. In some example embodiments, the upper overlay 350 may be or may include a photoresist pattern and/or an anti-reflective coating (ARC) pattern and/or a hardmask pattern. However, example embodiments are not limited thereto.

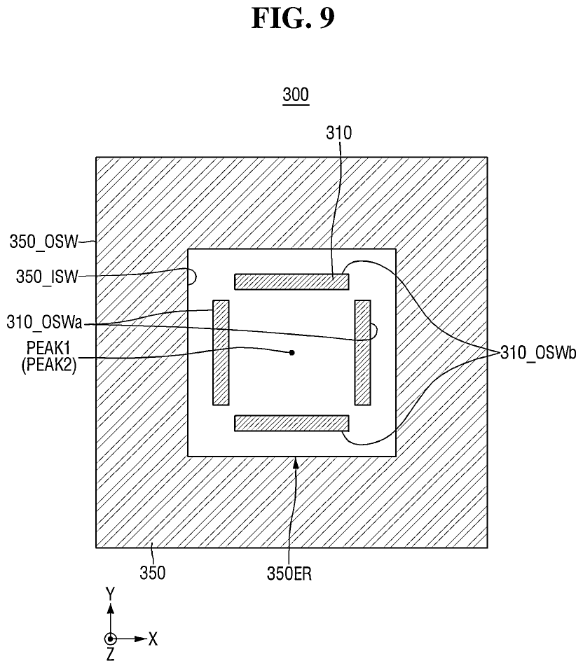

In some example embodiments, the lower overlay 310 does not overlap the upper overlay 350 in the thickness direction of the substrate 100, for example, the third direction Z. For example, the lower overlay 310 is completely overlapped by the opening 350ER in the third direction Z. Since there is a structure in which the lower overlay 310 and the upper overlay 350 do not overlap each other in the third direction Z, it may be easier to measure a first peak value (PEAK1 of FIG. 9) of the lower overlay 310, which will be described below. Therefore, misalignment of the pattern may be inspected more accurately, and a semiconductor device may be more accurately fabricated based on the misalignment.

In some example embodiments, the lower overlay 310 may include outer walls 310_OSW that are opposite to each other. In FIG. 3, the outer walls 310_OSW of the lower overlay 310 may include a pair extending in the first direction X and a pair extending in the second direction Y.

In some example embodiments, a distance d1 between the outer walls 310_OSW of the lower overlay 310 may be 6 μm or more and 9 μm or less. For example, the distance d1 in the first direction X between the outer walls 310_OSW of the lower overlay 310 may be 6 μm or more and 9 μm or less. Since the distance d1 between the outer walls 310_OSW of the lower overlay 310 is 9 μm or less, the lower overlay 310 and the upper overlay 350 may not overlap each other in the third direction Z.

In some example embodiments, the lower overlay 310 may include an inner wall 310_ISW opposite to an outer wall 310_OSW. The inner walls 310_ISW of the pair of lower overlays 310 may face each other. For example, the inner walls 310_ISW of the lower overlay 310 may include a pair extending in the first direction X, and a pair extending in the second direction Y.

In some example embodiments, a width 310W of the lower overlay 310 may be 1 μm or more. A distance between the outer wall 310_OSW of the lower overlay 310 and the inner wall 310_ISW opposite to the outer wall 310_OSW of the lower overlay 310 may be 1 μm or more. However, the embodiment is not limited thereto.

In some example embodiments, the upper overlay 350 may include outer walls 350_OSW opposite to each other. The outer walls 350_OSW of the upper overlay 350 may include a pair extending in the first direction X and a pair extending in the second direction Y.

In some example embodiments, a distance d3 between the outer walls 350_OSW of the upper overlay 350 may be 30 μm or more and 35 μm or less. For example, the distance d3 in the first direction X between the outer walls 350_OSW of the upper overlay 350 may be 30 μm or more and 35 μm or less.

In some example embodiments, the upper overlay 350 may include an inner wall 350_ISW opposite to the outer wall 350_OSW. The inner wall 350_ISW of the upper overlay 350 may define an opening 350ER. The inner walls 350_ISW of the pair of upper overlays 350 may face each other. For example, the inner walls 350_ISW of the upper overlay 350 may include a pair extending in the first direction X, and a pair extending in the second direction Y.

In some example embodiments, although a distance d2 between the outer wall 350_OSW of the upper overlay 350 and the inner wall 350_ISW opposite to the outer wall 350_OSW of the upper overlay 350 may be 10 μm or more, the embodiment is not limited thereto.

In some example embodiments, the inner walls 350_ISW of the upper overlay 350 may have a slope. For example, an angle formed between the inner wall 350_ISW of the upper overlay 350 and the upper surface of the pattern layer 330 is not 90°. That is, the inner wall 350_ISW of the upper overlay 350 does not extend in a direction parallel to the third direction Z.

In some example embodiments, a width 350ER_W of the opening 350ER may be 10 μm or more and 15 μm or less. The width 350ER_W of the opening 350ER may be greater than the distance d1 between the outer walls 310_OSW of the lower overlay 310. Therefore, the opening 350ER may completely overlap the lower overlay 310 in the third direction Z.

In some example embodiments, a distance d4 between the inner wall 350_ISW of the upper overlay 350 and the outer wall 310_OSW of the lower overlay 310 may be 1.5 μm or more and 3.0 μm or less. However, the embodiment is not limited thereto.

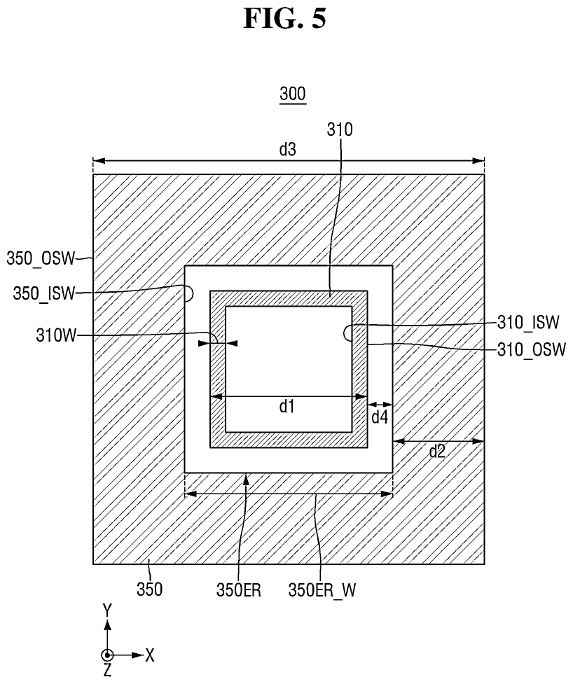

FIG. 5 is a plan view for explaining the overlay mark according to some example embodiments. For convenience of explanation, the explanation will focus on points different from those explained using FIGS. 3 and 4.

Referring to FIG. 5, the lower overlay 310 may have a frame shape from a planar viewpoint. That is, the lower overlay 310 may have a closed curve shape of a square form. The outer walls 310_OSW of the lower overlay 310 may be connected together. The inner walls 310_ISW of the lower overlay 310 may be connected together. Even when the lower overlay 310 has a frame shape, the distance d1 between the outer walls 310_OSW of the lower overlay 310 may be 6 μm or more and 9 μm or less.

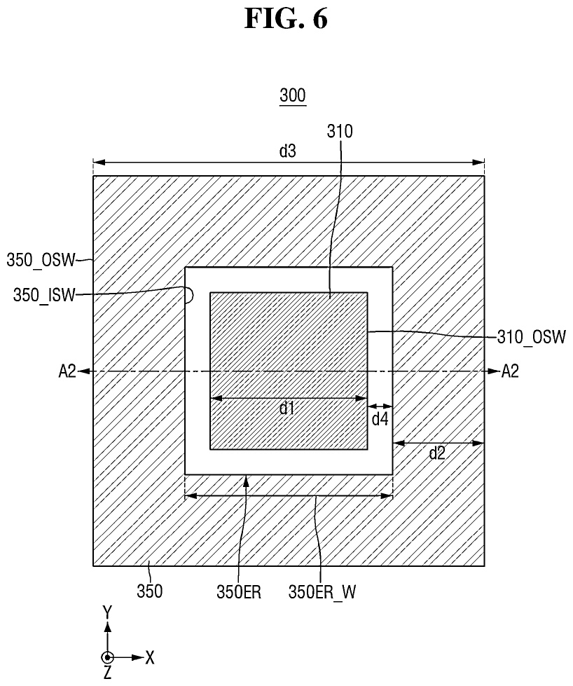

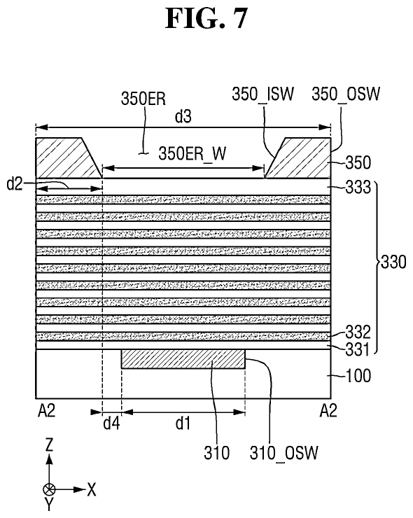

FIG. 6 is a plan view for explaining the overlay mark according to some example embodiments. FIG. 7 is a cross-sectional view taken along line A2-A2 of FIG. 6. For convenience of explanation, the explanation will focus on points different from those explained using FIGS. 3 and 4.

Referring to FIGS. 6 and 7, the lower overlay 310 may have a box shape from a planar viewpoint. The lower overlay 310 does not include inner walls. The lower overlay 310 may completely fill the inside of the outer wall 310_OSW of the lower overlay 310. Even when the lower overlay 310 has a box shape, the distance d1 between the outer walls 310_OSW of the lower overlay 310 may be 6 μm or more and 9 μm or less.

A pattern misalignment inspection method using the overlay mark according to some example embodiments will be described below.

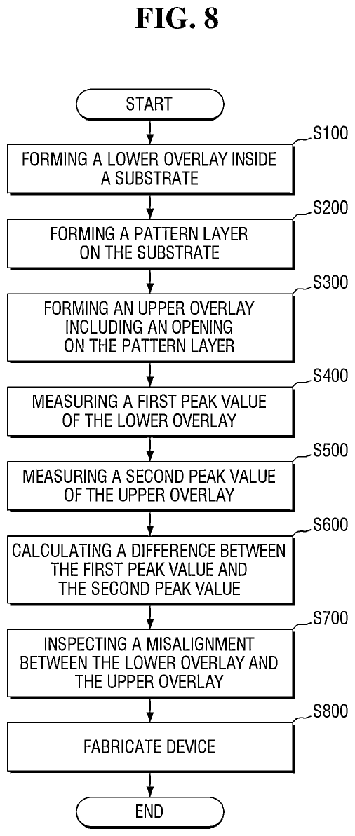

FIG. 8 is a flow chart for explaining the pattern misalignment inspection method using the overlay mark according to some example embodiments.

First, referring to FIGS. 4 and 8, the pattern misalignment inspection method using the overlay marks may include forming of the lower overlay 310 inside the substrate 100 (S100). A part of the substrate 100 may be etched to form the lower overlay 310.

Subsequently, the pattern layer 330 may be formed on the substrate 100 (S200). First, the first insulating layer 331 and the second insulating layer 332 are alternately stacked, and then the third insulating layer 333 may be formed.

Next, the upper overlay 350 including the opening 350ER may be formed on the pattern layer 330 (S300). The upper overlay 350 may be a photoresist pattern. As the thickness of the upper overlay 350 in the third direction Z increases, the inner wall 350_ISW of the upper overlay 350 may have a slope.

Next, a first peak value PEAK1 of the lower overlay 310 may be measured (S400). The first peak value (PEAK1 of FIG. 9) may be a median value of the distance between the outer walls 310_OSW of the lower overlay 310. For example, in FIG. 9, the outer wall 310_OSWb of the lower overlay 310 may include a first pair 310_OSWa and a second pair 310_OSWb. The first pair 310_OSWa may extend in the second Y direction. The second pair 310_OSWb may extend in the first direction X.

The first peak value PEAK1 may be represented by an x value and a y value. The x value may be a median value of the distance by which the first pair 310_OSWa are separated from each other. The y value may be a median value of the distance by which the second pair 310_OSWb are separated from each other.

Subsequently, a second peak value (PEAK2 of FIG. 9) of the upper overlay 350 may be measured (S500). As an example, the second peak value PEAK2 may be a median value of the width of the opening 350ER. As another example, the second peak value PEAK2 may be a center of gravity of the opening 350ER.

For example, the second peak value PEAK2 may be represented by an x value and a y value. The x value may be a median value of the width in the first direction X of the opening 350ER. The y value may be a median value of the width in the second direction Y of the opening 350ER.

Subsequently, a difference between the first peak value PEAK1 and the second peak value PEAK2 may be calculated (S600). The difference between the first peak value PEAK1 and the second peak value PEAK2 may be calculated to inspect the misalignment between the lower overlay 310 and the upper overlay 350 (S700).

In some example embodiments, a semiconductor device, such as a semiconductor memory device, may be fabricated (S800). For example, a semiconductor device may be fabricated based on the misalignment.

In some example embodiments, the above procedure may be repeated at a plurality of positions. A difference between the first peak value PEAK1 and the second peak value PEAK2 at each of the plurality of positions is calculated, and misalignment between the lower overlay 310 and the upper overlay 350 may be inspected on the basis of the calculated data.

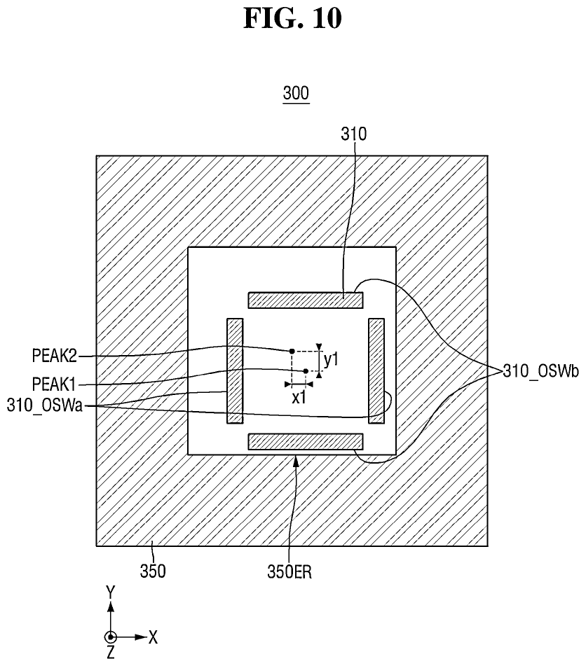

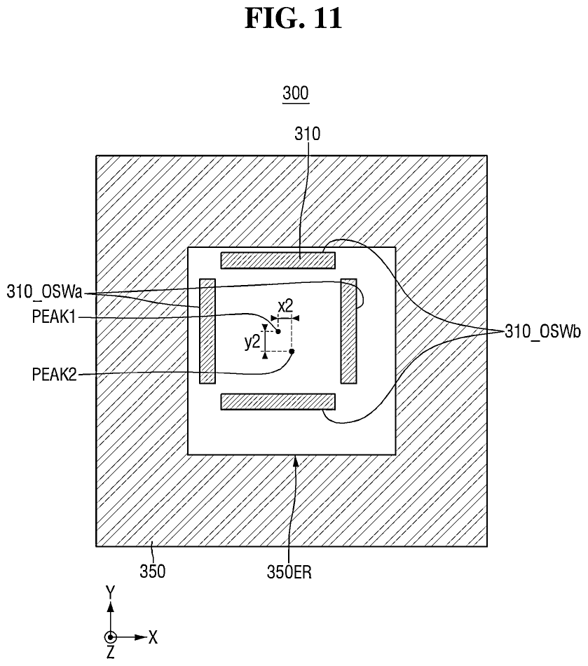

FIGS. 9 to 11 are example diagrams for explaining a pattern misalignment inspection method using the overlay mark according to some example embodiments. For reference, FIG. 9 may be a diagram showing that the lower overlay and the upper overlay are aligned, and FIGS. 10 and 11 may be diagrams each showing that the lower overlay and the upper overlay are misaligned. Further, FIGS. 9 to 11 are diagrams showing an overlay mark placed at different positions from each other.

First, referring to FIG. 9, the first peak value PEAK1 may be the same as the second peak value PEAK2. In this case, a difference between the first peak value PEAK1 and the second peak value PEAK2 may be represented by (0, 0).

Referring to FIG. 10, the first peak value PEAK1 may differ from the second peak value PEAK2. The second peak value PEAK2 may be spaced apart from the first peak value PEAK1 by x 1 in a—first direction (—X direction). The second peak value PEAK2 may be spaced apart from the first peak value PEAK1 by y1 in the second direction (Y direction). That is, the difference between the first peak value PEAK1 and the second peak value PEAK2 may be represented by (−x1, y1).

Referring to FIG. 11, the first peak value PEAK1 may differ from the second peak value PEAK2. The second peak value PEAK2 may be spaced apart from the first peak value PEAK1 by x2 in the first direction (X direction). The second peak value PEAK2 may be spaced apart from the first peak value PEAK1 by y2 in a—second direction (— Y direction). That is, the difference between the first peak value PEAK1 and the second peak value PEAK2 may be represented by (x2, −y2).

In some example embodiments, misalignment of the pattern may be inspected, using the data of (0, 0), (−x1, y1), and (x2, −y2). When using the overlay mark 300 according to some example embodiments, the upper overlay 350 does not overlap the lower overlay 310 in the third direction Z. Therefore, the first peak value PEAK1 of the lower overlay 310 may be easily measured. Accordingly, it may be possible to provide a pattern misalignment inspection method having improved reliability and/or an improved process of fabricating certain semiconductor devices.

A non-volatile memory device manufactured using the overlay mark according to some example embodiments will be described below.

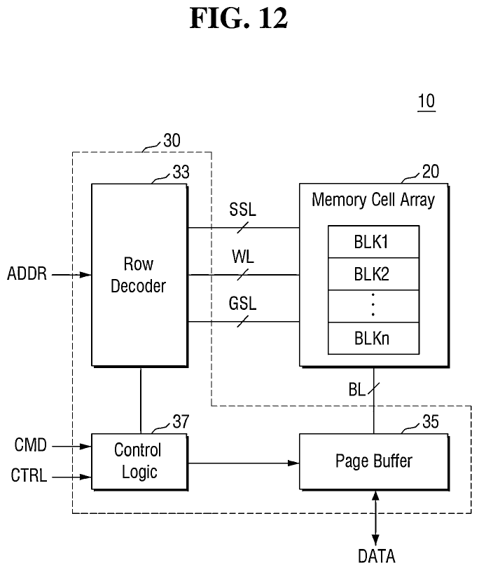

FIG. 12 is an example block diagram for explaining the non-volatile memory device according to some example embodiments.

Referring to FIG. 12, a non-volatile memory device 10 according to some example embodiments includes a memory cell array 20 and a peripheral circuit 30.

The memory cell array 20 may include a plurality of memory cell blocks (BLK1 to BLKn). Each memory cell block BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to the row decoder 33 through the word line WL, the string selection line SSL, and the ground selection line GSL. Also, the memory cell blocks BLK1 to BLKn may be connected to the page buffer 35 through the bit line BL.

The peripheral circuit 30 may receive an address (ADDR), a command (CMD) and a control signal (CTRL) from the outside of the non-volatile memory device 10, and may send and receive data (DATA) to and from a device outside the non-volatile memory device 10. The peripheral circuit 30 may include a control logic 37, a row decoder 33, and a page buffer 35. Although not shown, the peripheral circuit 30 may further include various sub-circuits such as an I/O circuit, a voltage generation circuit that generates various voltages necessary for the operation of the non-volatile memory device 10, and an error correction circuit for correcting an error of the data (DATA) read from the memory cell array 20.

The control logic 37 may be connected to the row decoder 33, the I/O circuit, and the voltage generation circuit. The control logic 37 may control the overall operation of the non-volatile memory device 10. The control logic 37 may generate various internal control signals used inside the non-volatile memory device 10 in response to the control signal CTRL. For example, the control logic 37 may adjust the voltage levels provided to the word line WL and the bit line BL when performing memory operations such as a program operation or an erase operation.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks (BLK1 to BLKn). The row decoder 33 may transfer a voltage for performing the memory operation to the word lines WL of the selected memory cell blocks (BLK1 to BLKn).

The page buffer 35 may be connected to the memory cell array 20 through the bit lines BL. The page buffer 35 may operate as a writer driver or a sense amplifier. Specifically, when performing the program operation, the page buffer 35 may operates as the writer driver to apply a voltage according to the data (DATA) to be stored in the memory cell array 20 to the bit line BL. On the other hand, when performing the read operation, the page buffer 35 may operate as the sense amplifier to sense the data (DATA) stored in the memory cell array 20.

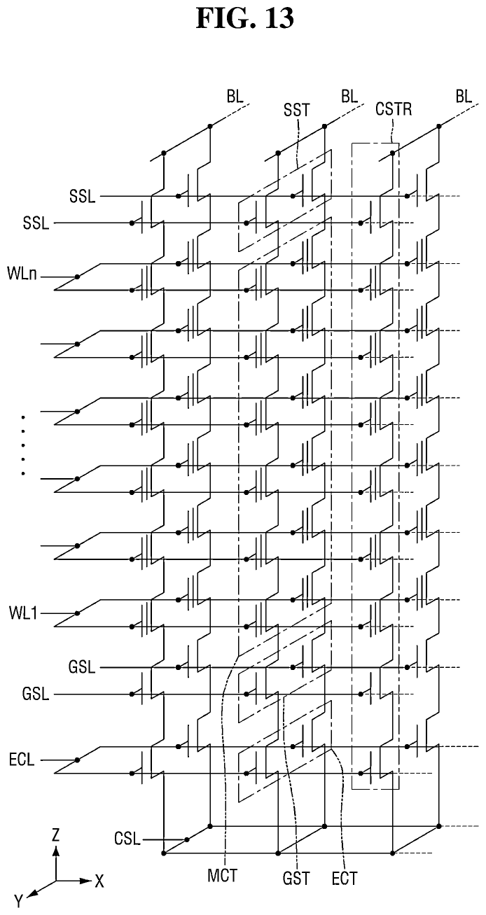

FIG. 13 is an example circuit diagram of a non-volatile semiconductor memory device according to some example embodiments.

Referring to FIG. 13, a memory cell array (e.g., 20 of FIG. 12) of the non-volatile semiconductor device according to some example embodiments may include a common source line CSL, a plurality of bit lines BL, and a plurality of cell strings CSTR.

The common source line CSL may extend in the first direction X. In some example embodiments, the plurality of common source lines CSL may be arranged two-dimensionally. For example, the plurality of common source lines CSL may extend in the first direction X, while being spaced apart from each other. The same voltage may be electrically applied to the common source lines CSL, or different voltages are applied to separately control the common source lines CSL.

A plurality of bit lines BL may be arranged two-dimensionally. For example, the bit lines BL may each extend in a second direction Y that intersects the first direction X, while being spaced apart from each other. A plurality of cell strings CSTR may be connected in parallel to each bit line BL. The cell strings CSTR may be commonly connected to the common source line CSL. That is, a plurality of cell strings CSTR may be placed between the bit line BL and the common source line CSL.

Each cell string CSTR may include a ground selection transistor GST connected to the common source line CSL, a string selection transistor SST connected to the bit line BL, and a plurality of memory cell transistors MCT placed between the ground selection transistor GST and the string selection transistor SST. Each memory cell transistor MCT may include a data storage element. The ground selection transistor GST, the string selection transistor SST, and the memory cell transistor MCT may be connected in series.

The common source line CSL may be commonly connected to the sources of the ground selection transistors GST. Also, the ground selection line GSL, the plurality of word lines (WL1 to WLn), and the string selection line SSL may be placed between the common source line CSL and the bit line BL. The ground selection line GSL may be used as the gate electrode of the ground selection transistor GST, the word lines (WL1 to WLn) may be used as the gate electrodes of the memory cell transistors MCT, and the string selection line SSL may be used as the gate electrode of the string selection transistor SST.

In some example embodiments, an erase control transistor ECT may be placed between the common source line CSL and the ground selection transistor GST. The common source line CSL may be commonly connected to the sources of the erase control transistors ECT. Also, an erase control line ECL may be placed between the common source line CSL and the ground selection line GSL. The erase control line ECL may be used as the gate electrode of the erase control transistor ECT. The erase control transistors ECT may generate gate induced drain leakage (GIDL) to perform the erase operation of the memory cell array.

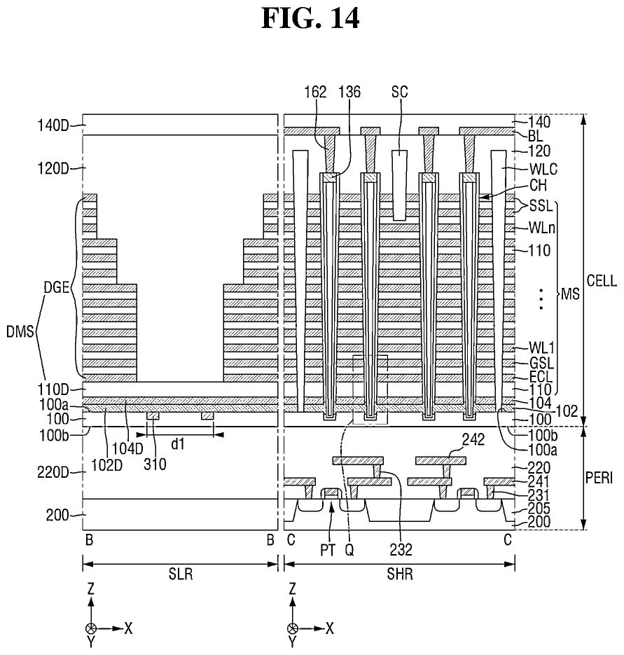

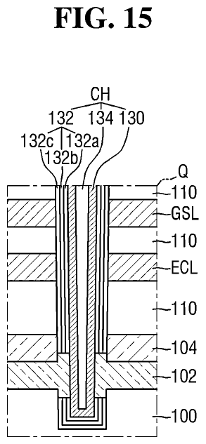

FIG. 14 is an example cross-sectional view taken along lines B-B and C-C of FIG. 2. FIG. 15 is an enlarged view of a region Q of FIG. 14.

Referring to FIGS. 14 and 15, a non-volatile memory device according to some example embodiments includes a shot region SHR and a scribe lane region SLR. The shot region SHR includes a cell structure CELL and a peripheral circuit structure PERI.

The cell structure CELL may include a substrate 100, a mold structure MS, an interlayer insulating film 120, a channel structure CH, a block isolation region WLC, a bit line BL, and a first inter-wiring insulating film 140. The substrate 100 may include a shot region SHR and a scribe lane region SLR.

The cell structure CELL may be provided with a memory cell array (e.g., 20 of FIG. 12) including a plurality of memory cells. For example, a channel structure CH, a bit line BL, gate electrodes (ECL, GSL, WL1 to WLn, and SSL), and the like, which will be described below, may be placed in the cell structure CELL. In the following description, the substrate 100 on which the memory cell array is placed, that is, a surface of the substrate 100 of the shot region SHR may be referred to as a front side 100a of the substrate 100. In contrast, a surface of the substrate 100 opposite to the front side of the substrate 100 may be referred to as a back side 100b of the substrate 100.

The mold structure MS may be provided on the front side 100a of the substrate 100. The mold structure MS may include a plurality of gate electrodes (ECL, GSL, WL1 to WLn, and SSL) and a plurality of mold insulating films 110 alternately stacked on the substrate 100. Each of the gate electrodes (ECL, GSL, WL1 to WLn, and SSL) and each mold insulating film 110 may extend parallel to the front side 100a of the substrate 100. The gate electrodes (ECL, GSL, WL1 to WLn, and SSL) are separated from each other by the mold insulating film 110 and sequentially stacked on the substrate 100.

In some example embodiments, the gate electrodes (ECL, GSL, WL1 to WLn, and SSL) may include an erase control line ECL, a ground selection line GSL, and a plurality of word lines (WL1 to WLn), which are sequentially stacked on the substrate 100. In some other embodiments, the erase control line ECL may be omitted.

The gate electrodes (ECL, GSL, WL1 to WLn, and SSL) may include, but are not limited to, conductive materials, for example, metals such as tungsten (W), cobalt (Co), nickel (Ni), and molybdenum (Mo), and semiconductor materials such as silicon. In an example, the gate electrodes (ECL, GSL, WL1 to WLn, and SSL) may each include tungsten (W) or molybdenum (Mo). The gate electrodes (ECL, GSL, WL1 to WLn, and SSL) may be multi-films, unlike the shown example. For example, when the gate electrodes (ECL, GSL, WL1 to WLn, and SSL) are multi-films, the gate electrodes (ECL, GSL, WL1 to WLn, and SSL) may include a gate electrode barrier film and a gate electrode filling film. The gate electrode barrier film may include, for example, titanium nitride (TiN), and the gate electrode filling film may include tungsten (W), but is not limited thereto. Preferably, the gate electrodes (ECL, GSL, WL1 to WLn, and SSL) may include tungsten (W).

The mold insulating film 110 may include an insulating material, for example, but is not limited to, at least one of silicon oxide, silicon nitride, and silicon oxynitride. For example, the mold insulating film 110 may include silicon oxide.

The interlayer insulating film 120 may be provided on the substrate 100. The interlayer insulating film 120 may cover the mold structure MS. The interlayer insulating film 120 may include an oxide-based insulating material. The interlayer insulating film 120 may include, for example, but is not limited to, at least one of silicon oxide, silicon oxynitride, and a low-k material having a lower dielectric constant than silicon oxide.

The channel structure CH may be provided inside the mold structure MS. The channel structure CH may extend in a vertical direction (hereinafter referred to as a third direction Z) intersecting the front side 100a of the substrate 100 to penetrate the mold structure MS. For example, the channel structure CH may have a pillar shape (for example, a cylindrical shape) extending in the third direction Z. Therefore, the channel structure CH may intersect each of the gate electrodes (ECL, GSL, WL1 to WLn, and SSL).

The channel structure CH may include a semiconductor pattern 130 and an information storage film 132.

The semiconductor pattern 130 may extend in the third direction Z and penetrate the mold structure MS. Although the semiconductor pattern 130 is only shown as a cup shape, this is only an example. For example, the semiconductor pattern 130 may have various shapes such as a cylindrical shape, a square barrel shape, and a solid filler shape. The semiconductor pattern 130 may include, for example, but is not limited to, semiconductor materials such as monocrystalline silicon, polycrystalline silicon, organic semiconductor material, and carbon nano structure.

The information storage film 132 may be interposed between the semiconductor pattern 130 and each of the gate electrodes (ECL, GSL, WL1 to WLn, and SSL). For example, the information storage film 132 may extend along the outer surface of the semiconductor pattern 130. The information storage film 132 may include, for example, at least one of silicon oxide, silicon nitride, silicon oxynitride, and a high dielectric constant material having a higher dielectric constant than silicon oxide. The high dielectric constant material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and combinations thereof.

In some example embodiments, the information storage film 132 may be formed of multi-films. For example, as shown in FIG. 15, the information storage film 132 may include a tunnel insulating film 132a, a charge storage film 132b and a blocking insulating film 132c which are sequentially stacked on the outer surface of the semiconductor pattern 130.

The tunnel insulating film 132a may include, for example, silicon oxide or a high dielectric constant material having a higher dielectric constant than silicon oxide (for example, aluminum oxide (Al₂O₃), and hafnium oxide (HfO₂)). The charge storage film 132b may include, for example, silicon nitride. The blocking insulating film 132c may include, for example, silicon oxide or a high dielectric constant material having a higher dielectric constant than silicon oxide (for example, aluminum oxide (Al₂O₃), and hafnium oxide (HfO₂)).

In some example embodiments, the channel structure CH may further include a filling pattern 134. The filling pattern 134 may be formed to fill the inside of the cup-shaped semiconductor pattern 130. The filling pattern 134 may include an insulating material for example, but is not limited to, silicon oxide.

In some example embodiments, the channel structure CH may further include a channel pad 136. The channel pad 136 may be formed to be connected to the semiconductor pattern 130. For example, the channel pad 136 is formed inside the interlayer insulating film 120, and may be connected to the upper part of the semiconductor pattern 130. The channel pad 136 may include, for example, but is not limited to, impurity-doped polysilicon.

In some example embodiments, a source layer 102 and a source support layer 104 may be sequentially formed on the substrate 100 of the shot region SHR. The source layer 102 and the source support layer 104 may be interposed between the substrate 100 of the shot region SHR and the mold structure MS. For example, the source layer 102 and the source support layer 104 may extend along the front side 100a of the substrate 100.

In some example embodiments, the source layer 102 may be formed to be connected to the semiconductor pattern 130 of the channel structure CH. For example, as shown in FIG. 15, the source layer 102 may penetrate the information storage film 132 and come into contact with the semiconductor pattern 130. Such a source layer 102 may be provided as a common source line (e.g., CSL of FIG. 13) of a non-volatile memory device. The source layer 102 may include, for example, but is not limited to, impurity-doped polysilicon or metal.

In some example embodiments, the channel structure CH may penetrate the source layer 102 and the source support layer 104. For example, the lower part of the channel structure CH penetrates the source layer 102 and the source support layer 104, and may be embedded in the substrate 100.

In some example embodiments, the source support layer 104 may be used as a support layer for preventing, or reducing the likelihood of, collapse and/or falling of the mold stack in a replacement process for forming the source layer 102.

Although not shown, a base insulating film may be interposed between the substrate 100 and the source layer 102 of the shot region SHR. The base insulating film may include, for example, but is not limited to, at least one of silicon oxide, silicon nitride and silicon oxynitride.

The block isolation region WLC may cut the mold structure MS. The mold structure MS may be cut by the plurality of block isolation regions WLC to form a plurality of memory cell blocks (e.g., BLK1 to BLKn of FIG. 12). For example, two adjacent block isolation regions WLC may define a single memory cell block therebetween. A plurality of channel structures CH may be placed inside each memory cell block defined by the block isolation region WLC.

In some example embodiments, the block isolation region WLC may cut the source layer 102 and the source support layer 104. Although a lower surface of the block isolation region WLC is only shown as being placed on the same plane as a lower surface of the source layer 102, this is only an example. As another example, the lower surface of the block isolation region WLC may be lower than the lower surface of the source layer 102.

In some example embodiments, the block isolation region WLC may include an insulating material. For example, the insulating material may fill the block isolation region WLC. The insulating material may include, for example, but is not limited to, at least one of silicon oxide, silicon nitride, and silicon oxynitride.

In some example embodiments, a string isolation structure SC may be provided inside the mold structure MS. The string isolation structure SC may extend in the first direction X to cut the string selection line SSL. Each memory cell block defined by the block isolation region WLC may be divided by the string isolation structure SC to form a plurality of string regions. For example, the string isolation structure SC may define two string regions inside the single memory cell block.

The bit line BL may be formed on the mold structure MS and the interlayer insulating film 120. The bit line BL may extend in the second direction Y and intersect the block isolation region WLC. Also, the bit line BL may extend in the second direction Y and be connected to a plurality of channel structures CH arranged along the second direction Y. For example, a bit line contact 162 connected to the upper parts of each channel structure CH may be formed inside the interlayer insulating film 120. The bit line BL may be electrically connected to the channel structures CH through the bit line contact 162.

In some example embodiments, the peripheral circuit structure PERI may be located on the back side 100b of the substrate 100 of the shot region SHR. The peripheral circuit structure PERI may include a peripheral circuit board 200 and a peripheral circuit element PT.

The peripheral circuit board 200 may be placed below the substrate 100. For example, the upper surface of the peripheral circuit board 200 may be opposite to the back side 100b of the substrate 100. The peripheral circuit board 200 may include a semiconductor substrate such as, for example, a silicon substrate, a germanium substrate or a silicon-germanium substrate. Alternatively, the peripheral circuit board 200 may include a silicon-on-insulator (SOI) substrate, a germanium-on-insulator (GOI) substrate, or the like.

The peripheral circuit element PT may be formed on the peripheral circuit board 200. The peripheral circuit element PT may constitute a peripheral circuit (e.g., 30 of FIG. 12) that controls the operation of the non-volatile memory device. For example, the peripheral circuit element PT may include a control logic (e.g., 37 of FIG. 12), a row decoder (e.g., ROW of FIG. 1), a page buffer (e.g., 35 of FIG. 1), and the like. In the following description, a surface of the peripheral circuit board 200 on which the peripheral circuit element PT is placed may be referred to as a front side of the peripheral circuit board 200. In contrast, a surface of the peripheral circuit board 200 opposite to the front side of the peripheral circuit board 200 may be referred to as a back side of the peripheral circuit board 200.

The peripheral circuit element PT may include, for example, but is not limited to, a transistor. For example, the peripheral circuit element PT may include not only various active elements such as a transistor, but also various passive elements such as a capacitor, a resistor and an inductor.

In some example embodiments, the back side 100b of the substrate 100 may be opposite to the front side of the peripheral circuit board 200. For example, a second inter-wiring insulating film 220 that covers the peripheral circuit elements PT may be formed on the front side of the peripheral circuit board 200. The substrate 100 may be stacked on the upper surface of the second inter-wiring insulating film 220.

First wiring patterns 241 and 242 connected to the peripheral circuit element PT may be formed inside the second inter-wiring insulating film 220. The first wiring patterns 241 and 242 may be connected to each other through first wiring contacts 231 and 232. Also, the first wiring patterns 241 and 242 may be electrically connected to the peripheral circuit element PT through the first wiring contacts 231 and 232. Therefore, the bit line BL, each of the gate electrodes (ECL, GSL, WL1 to WLn, and SSL), and/or the source layer 102 may be electrically connected to the peripheral circuit element PT.

The peripheral circuit elements PT may be separated by a peripheral element isolation film 205. For example, the peripheral element isolation film 205 may be provided inside the peripheral circuit board 200. The peripheral isolation film 205 may be or may include a shallow element isolation (shallow trench isolation; STI) film. The peripheral element isolation film 205 may define an active region of the peripheral circuit elements PT. The peripheral element isolation film 205 may include an insulating material. The peripheral element isolation film 205 may include, for example, at least one of silicon nitride, silicon oxide, and silicon oxynitride.

A lower overlay 310 may be placed inside the substrate 100 of the scribe lane region SLR. The lower overlay 310 may be formed of a material different from the substrate 100 of the scribe lane region SLR. As an example, the lower overlay 310 may be formed of, but is not limited to, silicon oxide film.

In some example embodiments, the lower overlay may include outer walls that are opposite to each other. A distance between the outer walls of the lower overlay is 6 μm or more and 9 μm or less.

A dummy mold structure DMS may be placed on the front side 100a of the substrate 100 of the scribe lane region SLR. The dummy mold structure DMS may include a plurality of dummy gate electrodes DGE and a plurality of dummy mold insulating films 110D that are alternately stacked on the substrate 100 of the scribe lane region SLR.

Each dummy gate electrode DGE and each dummy mold insulating film 110D may have a layered structure extending parallel to the front side 100a of the substrate 100 of the scribe lane region SLR. The dummy gate electrodes DGE are spaced apart from each other by the dummy mold insulating film 110D and sequentially stacked on the substrate 100 of the scribe lane region SLR. The dummy gate electrodes DGE may be formed of the same material as the gate electrodes (ECL, GSL, WL1 to WLn, and SSL). The dummy mold insulating films 110D may be formed of the same material as the mold insulating film 110.

In some example embodiments, the dummy mold structure DMS may have a step shape. This may be due to the process appearing in the procedure of forming the mold structure MS of the shot region SHR.

In some example embodiments, a dummy source layer 102D and a dummy source support layer 104D may be placed between the substrate 100 of the scribe lane region SLR and the dummy mold structure DMS. For example, the dummy source layer 102D and the dummy source support layer 104D may extend along the front side 100a of the substrate 100 of the scribe lane region SLR. The dummy source layer 102D may include, for example, but is not limited to, impurity-doped polysilicon or metal.

In some example embodiments, a dummy interlayer insulating film 120D may be placed on the dummy mold structure DMS. The dummy interlayer insulating film 120D may cover the dummy mold structure DMS. The dummy interlayer insulating film 120D may include an oxide-based insulating material. The dummy interlayer insulating film 120D may include, for example, but is not limited to, at least one of silicon oxide, silicon oxynitride, and a low-k material having a lower dielectric constant than silicon oxide.

A dummy first inter-wiring insulating film 140D may be placed on the dummy interlayer insulating film 120D. The dummy first inter-wiring insulating film 140D may be formed at the same level as the first inter-wiring insulating film 140 of the shot region SHR.

In some example embodiments, a dummy second inter-wiring insulating film 220D may be formed on the peripheral circuit board 200 of the scribe lane region SLR. The dummy second inter-wiring insulating film 220D may be formed at the same level as the second inter-wiring insulating film 220.

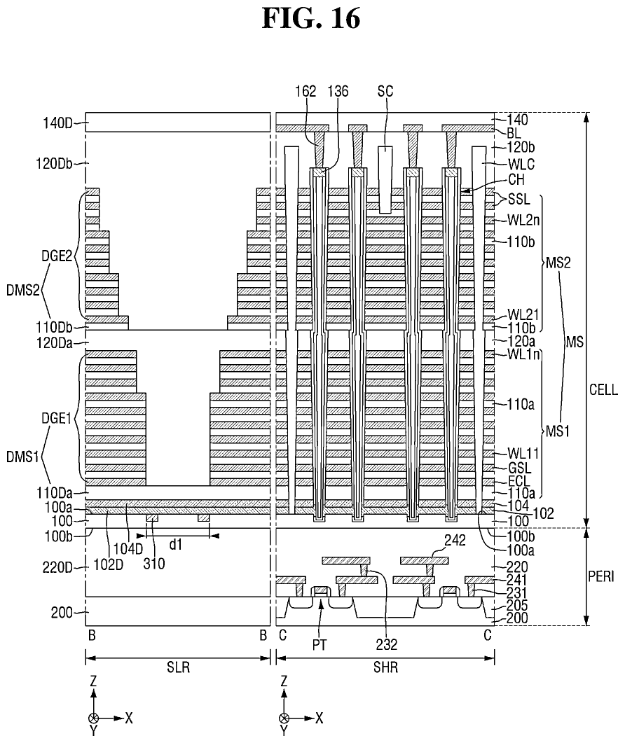

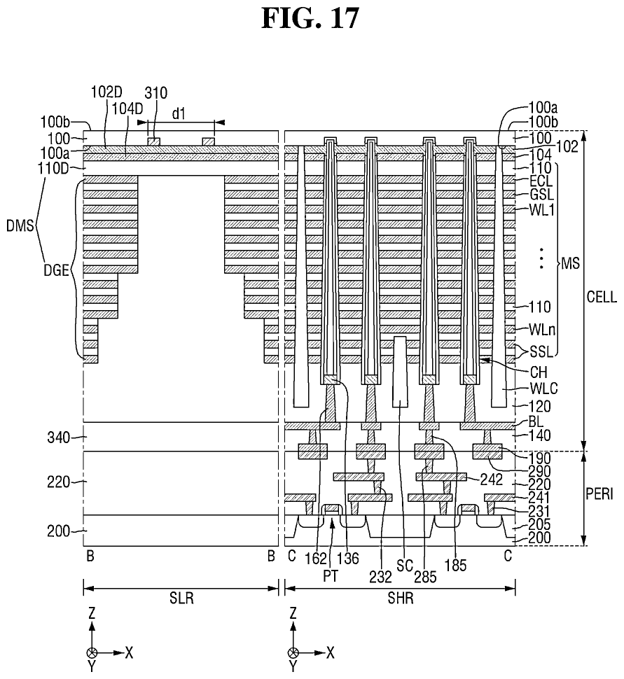

FIGS. 16 and 17 are example diagrams for explaining a non-volatile memory device according to some example embodiments. For convenience of explanation, repeated content of those explained using FIGS. 12 to 15 will be omitted.

First, referring to FIG. 16, a non-volatile memory device according to some example embodiments may be a 2-stack non-volatile memory device. For example, the mold structure MS may include a lower mold structure MS1 and an upper mold structure MS2. The upper mold structure MS2 may be placed on the lower mold structure MS1.

The lower mold structure MS1 may include a plurality of lower gate electrodes (ECL, GSL, and WL11 to WL1n) and a plurality of lower mold insulating films 110a alternately stacked on the substrate 100 of the shot region SHR. The plurality of lower gate electrodes (ECL, GSL, and WL11 to WL1n) and the plurality of lower mold insulating films 110a may extend parallel to the front side 100a of the substrate 100.

The upper mold structure MS2 may include a plurality of upper gate electrodes (WL21 to WL2n and SSL), and a plurality of upper mold insulating films 110b that are alternately stacked on the lower mold structure MS1. The plurality of upper gate electrodes (WL21 to WL2n and SSL), and the plurality of upper mold insulating films 110b may extend parallel to the upper surface of the substrate 100.

In some example embodiments, the interlayer insulating film 120 may include a lower interlayer insulating film 120a and an upper interlayer insulating film 120b. The upper interlayer insulating film 120b may be placed on the lower interlayer insulating film 120a. Each of the lower interlayer insulating film 120a and the upper interlayer insulating film 120b may include, for example, but are not limited to, at least one of silicon oxide, silicon oxynitride, and a low-k material having a lower dielectric constant than silicon oxide.

In some example embodiments, the dummy mold structure DMS may include a lower dummy mold structure DMS1 and an upper dummy mold structure DMS2. The upper dummy mold structure DMS2 may be placed on the lower dummy mold structure DMS1.

The lower dummy mold structure DMS1 may include a plurality of lower dummy gate electrodes DGE1 and a plurality of lower dummy mold insulating films 110 Da which are alternately stacked on the substrate 100 of the scribe lane region SLR. The plurality of lower dummy gate electrodes DGE1 and the plurality of lower dummy mold insulating films 110 Da may extend parallel to the front side 100a of the substrate 100.

The upper dummy mold structure DMS2 may include a plurality of upper dummy gate electrodes DGE2 and a plurality of upper dummy mold insulating films 110Db which are alternately stacked on the lower dummy mold structure DMS1. The plurality of upper dummy gate electrodes DGE2 and the plurality of upper dummy mold insulating films 110Db may extend parallel to the front side 100a of the substrate 100.

In some example embodiments, the dummy interlayer insulating film 120D may include a lower dummy interlayer insulating film 120 Da and an upper dummy interlayer insulating film 120Db. The upper dummy interlayer insulating film 120Db may be placed on the lower dummy interlayer insulating film 120 Da. Each of the lower dummy interlayer insulating film 120 Da and the upper dummy interlayer insulating film 120Db may include, for example, but is not limited to, at least one of silicon oxide, silicon oxynitride, and a low dielectric constant (low-k) material having a smaller dielectric constant than silicon oxide.

Referring to FIG. 17, the front side 100a of the substrate 100 faces the front side of the peripheral circuit board 200 in the non-volatile memory device according to some example embodiments.

For example, the non-volatile memory device according to some example embodiments may be a C2C (chip-to-chip) structure. The C2C structure may mean a structure in which an upper chip including a cell structure CELL is manufactured on a first wafer (e.g., the substrate 100), and a lower chip including a peripheral circuit structure PERI is manufactured on a second wafer different from the first wafer, and then, the upper chip and the lower chip are connected to each other by a bonding method. The peripheral circuit structure PERI may be placed on the front side 100b of the substrate 100 of the shot region SHR.

As an example, the bonding method may mean a method of electrically connecting a first bonding metal 190 formed on the uppermost metal layer of the upper chip and a second bonding metal 290 formed on the uppermost metal layer of the lower chip to each other. For example, when the first bonding metal 190 and the second bonding metal 290 are formed of copper (Cu), the bonding method may be a Cu—Cu bonding method. However, this is only an example, and needless to say, the first bonding metal 190 and the second bonding metal 290 may be formed of various other metals such as aluminum (Al) or tungsten (W).

As the first bonding metal 190 and the second bonding metal 290 are connected, the bit line BL may be connected with the first wiring patterns 241 and 242. For example, the first bonding metal 190 and the bit line BL may be connected to each other through the second wiring contact 185. The second bonding metal 290 and the first wiring patterns 241 and 242 may be connected to each other through a third wiring contact 285. Therefore, each of the gate electrodes (ECL, GSL, WL1 to WLn, and SSL) and/or the source layer 102 may be electrically connected to the peripheral circuit element PT. The second wiring contact 185 and the third wiring contact 285 may each include, but are not limited to, tungsten (W) or copper (Cu).

An electronic system including the non-volatile memory device according to example embodiments will be described below referring to FIGS. 12 to 14 and 18 to 20.

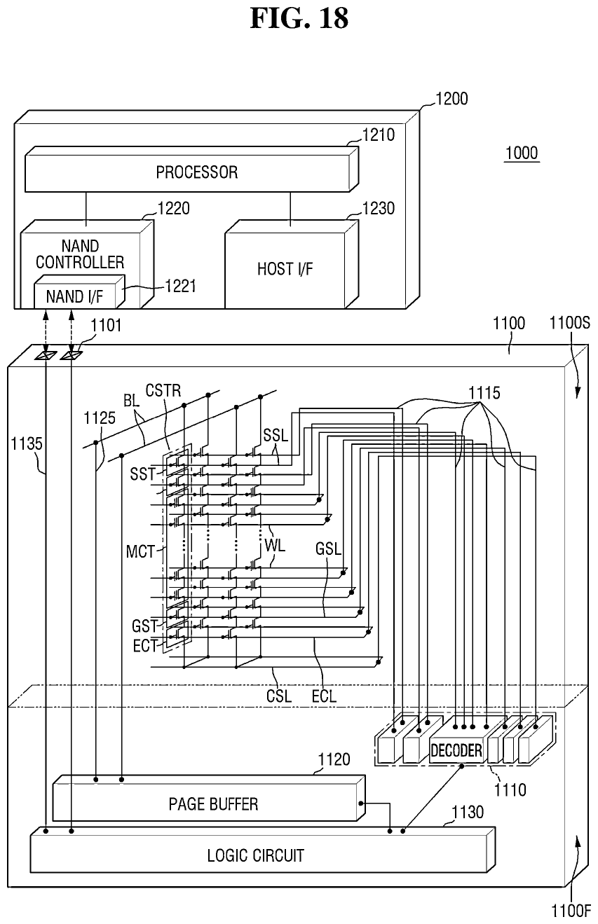

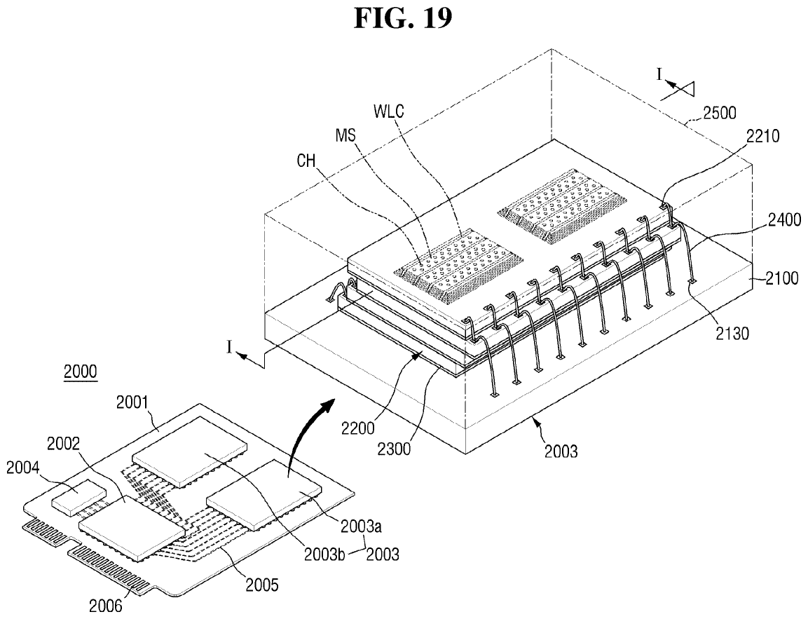

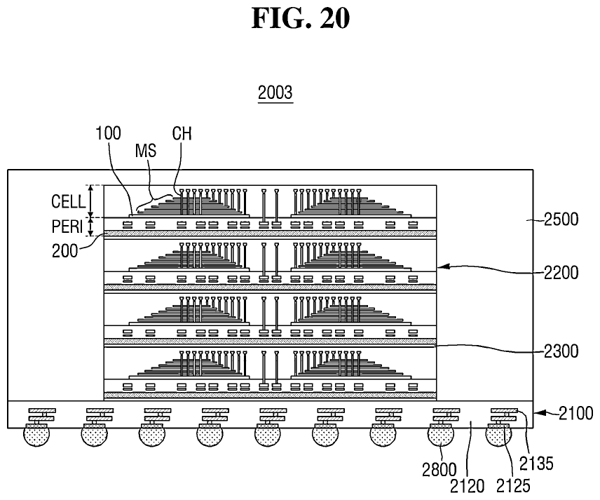

FIG. 18 is an example block diagram for explaining an electronic system according to some example embodiments. FIG. 19 is an example perspective view for explaining the electronic system according to some example embodiments. FIG. 20 is a schematic cross-sectional view taken along a line I-I of FIG. 19.

Referring to FIG. 18, an electronic system 1000 according to some example embodiments may include a non-volatile memory device 1100, and a controller 1200 that is electrically connected to the non-volatile memory device 1100. The electronic system 1000 may be a storage device that includes one or multiple non-volatile memory devices 1100, or an electronic device that includes the storage device. For example, the electronic system 1000 may be an SSD device (solid state drive device), a USB (Universal Serial Bus), a computing system, a medical device or a communication device that includes one or multiple non-volatile memory devices 1100.

The non-volatile memory device 1100 may be a NAND flash memory device, and may be, for example, the non-volatile memory device explained above using FIGS. 12 to 17. The non-volatile memory device 1100 may include a first structure 1100F, and a second structure 1100S on the first structure 1100F.

The first structure 1100F may be a peripheral circuit structure that includes include a decoder circuit 1110 (e.g., a row decoder 33 of FIG. 12), a page buffer 1120 (e.g., a page buffer 35 of FIG. 12), and a logic circuit 1130 (e.g., a control logic 37 of FIG. 12).

The second structure 1100S may include the common source line CSL, multiple bit lines BL, and multiple cell strings CSTR explained above using FIG. 13. The cell strings CSTR may be connected to the decoder circuit 1110 through the word line WL, at least one string selection line SSL, and at least one ground selection line GSL. In addition, the cell strings CSTR may be connected to the page buffer 1120 through the bit the lines BL.

In some example embodiments, the common source line CSL and the cell strings CSTR may be electrically connected to the decoder circuit 1110 through first connection wirings 1115 extending from the first structure 1100F to the second structure 1100S.

In some example embodiments, the bit lines BL may be electrically connected to the page buffer 1120 through second connection wirings 1125 extending from the first structure 1100F to the second structure 1100S.

The non-volatile memory device 1100 may communicate with the controller 1200 through the I/O pads 1101 electrically connected to the logic circuit 1130 (e.g., the control logic 37 of FIG. 12). The I/O pad 1101 may be electrically connected to the logic circuit 1130 through the I/O connection wiring 1135 extending from inside of the first structure 1100F to the second structure 1100S.

The controller 1200 may include a processor 1210, a NAND controller 1220, and a host interface 1230. In some example embodiments, the electronic system 1000 may include a plurality of non-volatile memory devices 1100, and in this case, the controller 1200 may control the plurality of non-volatile memory devices 1100.

The processor 1210 may control the operation of the overall electronic system 1000 including the controller 1200. The processor 1210 may operate according to a predetermined firmware, and may control the NAND controller 1220 to access the non-volatile memory device 1100. The NAND controller 1220 may include a NAND interface 1221 that processes communication with the non-volatile memory device 1100. Control command for controlling the non-volatile memory device 1100, data to be recorded in the memory cell transistors MCT of the non-volatile memory device 1100, data to be read from the memory cell transistors MCT of the non-volatile memory device 1100, and the like may be transmitted through the NAND interface 1221. The host interface 1230 may provide a communication function between the electronic system 1000 and an external host. When receiving the control command from the external host through the host interface 1230, the processor 1210 may control the non-volatile memory device 1100 in response to the control command.

Referring to FIGS. 18 to 20, the electronic system according to some example embodiments may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of pins coupled to an external host. In the connector 2006, the number and placement of the plurality of pins may vary depending on the communication interface between the electronic system 2000 and the external host. In some example embodiments, the electronic system 2000 may communicate with the external host according to any one of interfaces such as M-Phy for USB

(Universal Serial Bus), PCI-Express (Peripheral Component Interconnect Express), SATA (Serial Advanced Technology Attachment), and UFS (Universal Flash Storage). In some example embodiments, the electronic system 2000 may operate by power supplied from the external host through the connector 2006. The electronic system 2000 may further include a PMIC (Power Management Integrated Circuit) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package that includes a plurality of semiconductor chips 2200. The first semiconductor package 2003a and the second semiconductor package 2003b may each include a package substrate 2100, semiconductor chips 2200 on the package substrate 2100, adhesive layers 2300 placed on the lower surfaces of each of the package chips 220, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 18.

In some example embodiments, the connecting structure 2400 may be a bonding wire that electrically connects the I/O pad 2101 and the package upper pads 2130. Therefore, in each of the first semiconductor package 2003a and the second semiconductor package 2003b, the semiconductor chips 2200 may be electrically connected to each other by a bonding wire method, and may be electrically connected to the package upper pads 2130 of the package substrate 2100. In some example embodiments, in each of the first semiconductor package 2003a and the second semiconductor package 2003b, the semiconductor chips 2200 may be electrically connected to each other by a connecting structure including a through electrode (Through Silicon Via, TSV) instead of the connecting structure 2400 of the bonding wire method.

In some example embodiments, the main controller 2002 and the semiconductor chips 2200 may also be included in a single package. In some example embodiments, the main controller 2002 and the semiconductor chips 2200 are mounted on a separate interposer substrate different from the main board 2001, and the main controller 2002 and the semiconductor chips 2200 may also be connected to each other by the wiring formed on the interposer substrate.

In some example embodiments, the package substrate 2100 may be a printed circuit board. The package substrate 2100 may include a package substrate body portion 2120, package upper pads 2130 placed on an upper side of the package substrate body portion 2120, lower pads 2125 placed on a lower side of the package substrate body portion 2120 or exposed through the lower side, and inner wirings 2135 that electrically connect the upper pads 2130 and the lower pads 2125 inside the package substrate body portion 2120. The upper pads 2130 may be electrically connected to the connecting structure 2400. The lower pads 2125 may be connected to the wiring patterns 2005 of the main board 2001 of the electronic system 2000 through conductive connections 2800 as in FIG. 18.

Referring to FIGS. 19 and 20, in the electronic system according to some example embodiments, each of the semiconductor chips 2200 may include the non-volatile memory device described above using FIGS. 12 to 17. For example, each of the semiconductor chips 2200 may include a peripheral circuit structure PERI, and a cell structure CELL stacked on the peripheral circuit structure PERI. As an example, the peripheral circuit structure PERI may include the peripheral circuit board 200 and the first wiring patterns 241 and 242 described above using FIGS. 12 to 17. Also, as an example, the cell structure CELL may include the substrate 100, the mold structure MS, the channel structure CH, the block isolation region WLC, and the bit line BL described above using FIGS. 14 to 17.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

In concluding the detailed description, those of ordinary skill in the art will appreciate that many variations and modifications may be made to various example embodiments without substantially departing from the principles of the present disclosure. Therefore, example embodiments are used in a generic and descriptive sense only and not for purposes of limitation. Furthermore, example embodiments are not necessarily mutually exclusive with one another. For example, some example embodiments may include one or more features described with reference to one or more figures, and may also include one or more other features described with reference to one or more other figures.

What is claimed is:

1. An overlay mark comprising:
a substrate;
a lower overlay in the substrate;
a pattern layer on the substrate; and
an upper overlay that defines an opening on the pattern layer,
wherein the lower overlay does not overlap the upper overlay in a thickness direction of the substrate.

2. The overlay mark of claim 1, wherein the lower overlay completely overlaps the opening in the thickness direction of the substrate.

3. The overlay mark of claim 1, wherein the upper overlay includes a photoresist pattern.

4. The overlay mark of claim 1, wherein the lower overlay includes outer walls opposite to each other, and a distance between the outer walls is 6 μm or more and 9 μm or less.

5. The overlay mark of claim 1, wherein
the upper overlay includes outer walls opposite to each other, and
a distance between the outer walls is 30 μm or more and 35 μm or less.

6. The overlay mark of claim 1, wherein the lower overlay has one or more of a bar shape in plan view or a frame shape in plan view.

7. The overlay mark of claim 6, wherein a width of the lower overlay is 1 μm or more.

8. The overlay mark of claim 1, wherein the lower overlay has a box shape in plan view.

9. The overlay mark of claim 1, wherein a width of the opening is 10 μm or more and 15 μm or less.

10. The overlay mark of claim 1, wherein a distance from an outer wall of the lower overlay to an inner wall of the upper overlay is 1.5 μm or more and 3.0 μm or less.

11. A semiconductor fabrication method comprising:
forming a lower overlay in a substrate;
forming a pattern layer on the substrate;
forming an upper overlay that defines an opening on the pattern layer, wherein the lower overlay completely overlaps the opening in a thickness of the substrate;
measuring a first peak value of the lower overlay;
measuring a second peak value of the upper overlay; and
calculating a difference between the first peak value and the second peak value.

12. The semiconductor fabrication method of claim 11, wherein the upper overlay is a photoresist pattern.

13. The semiconductor fabrication method of claim 11, wherein a width of the opening is 10 μm or more and 15 μm or less.

14. The semiconductor fabrication method of claim 11, wherein the second peak value corresponds to a median value of a width of the opening.

15. The semiconductor fabrication method of claim 11, wherein
the lower overlay includes outer walls opposite to each other, and
a distance between the outer walls is 6 μm or more and 9 μm or less.

16. The semiconductor fabrication method of claim 15, wherein the first peak value corresponds to a median value of a distance between the outer walls of the lower overlay.

17. The semiconductor fabrication method of claim 11, wherein the lower overlay includes at least one of a bar shape, a frame shape, and a box shape from a planar viewpoint.

18. A semiconductor device comprising:
a substrate including a shot region, and a scribe lane region surrounding the shot region;
a mold structure on the substrate of the shot region, and including a plurality of gate electrodes and a plurality of mold insulating films alternately stacked;
a dummy mold structure on the substrate of the scribe lane region, and including a plurality of dummy gate electrodes and a plurality of dummy mold insulating films alternately stacked;
a channel structure which penetrates the mold structure and is connected to the plurality of gate electrodes; and
a lower overlay in the substrate of the scribe lane region,
wherein the lower overlay includes outer walls opposite to each other, and
a distance between the outer walls is 6 μm (micron) or more and 9 μm (micron) or less.

19. The semiconductor device of claim 18, wherein
the substrate includes a back side and a front side that are opposite to each other,
the mold structure is placed on the front side, and
the semiconductor device further comprises a peripheral circuit structure on the back side.

20. The semiconductor device of claim 18, wherein
the substrate includes a back side and a front side that are opposite to each other,
the mold structure is on the front side, and
the semiconductor device further comprises a peripheral circuit structure placed on the front side.
